(19) United States
(12) Patent Application Publication
(10) Pub. No.: US 2022/0028634 A1
(43) Pub. Date: Jan. 27, 2022

(54) ROTATABLY CONTROLLED EARPHONE

(71) Applicant: SHENZHEN QIANHAI PATUOXUN NETWORK AND TECHNOLOGY CO., LTD., Shenzhen (CN)

(72) Inventors: Yanan He, Shenzhen (CN); Zhangjian Lai, Shenzhen (CN); Wuxi Yang, Shenzhen (CN); Fangxiang Zhu, Shenzhen (CN)

(21) Appl. No.: 17/383,230

(22) Filed: Jul. 22, 2021

(30) Foreign Application Priority Data
Jul. 24, 2020 (CN) 202021494875.9

(51) Int. Cl. H01H 19/14; H04R 1/10; G01D 5/14

(52) U.S. Cl. CPC H01H 19/14; G01D 5/145; H04R 1/1041; H04R 1/1016

(57) ABSTRACT

Provided is a rotatably controlled earphone including a housing, a circuit board, a Hall sensor, and a magnetic knob. The circuit board is disposed in the housing. The Hall sensor is disposed in the housing and electrically connected to the circuit board. The magnetic knob is rotatably disposed on an outer peripheral wall surface of the housing and cooperates with the Hall sensor. The rotatably controlled earphone achieves adjustment functions of increasing/decreasing volume, adjusting a depth of noise reduction, switching to a last song or a next song and the like by rotating a mounting shell, facilitating the use of the earphone, simplifying the structure of the earphone, reducing the production cost of the earphone, controlling the volume of the earphone and being convenient for a user to find and rotate, thereby increasing the using satisfaction of the user.

### CROSS-REFERENCE TO RELATED APPLICATION

This application claims priority to Chinese Patent Application No. 202021494875.9 filed on Jul. 24, 2020, the disclosure of which is incorporated herein by reference in its entirety.

### TECHNICAL FIELD

The present disclosure relates to the technical field of earphones, and in particular, to a rotatably controlled earphone.

### BACKGROUND

With the rapid development of bluetooth wireless earphones and various sensor technologies, various new earphones are constantly on the market. Through the cooperation of various sensors, the earphone can be controlled in various modes, such as mechanical key control, touch control, voice control, gesture control, or the like.

Currently, most earphones are controlled in a mode of mechanical key control or touch control. After the earphone is put on ears, since eyes are unable to see a position of a key and the key is relatively small, the operation difficulty of a user is increased. Currently, the rotatably controlled earphone is basically achieved by an encoder. Since the encoder needs to occupy a large space, a volume of the earphone is increased. In addition, the encoder has a relatively complex structure design, so the manufacturing cost of the earphone is relatively high.

### SUMMARY

The present disclosure provides a rotatably controlled earphone. The earphone is convenient to control, simple in structure, small in volume and low in manufacturing costs.

To achieve the above technical effects, technical solutions of embodiments are described below.

The present disclosure provides a rotatably controlled earphone. The earphone includes a housing, a circuit board, a Hall sensor, and a magnetic knob. The circuit board is disposed in the housing. The Hall sensor is disposed in the housing and electrically connected to the circuit board. The magnetic knob is rotatably disposed on an outer peripheral wall surface of the housing and cooperates with the Hall sensor.

In an embodiment, the magnetic knob includes a mounting shell and a magnet, the mounting shell has an assembly groove, and the magnet is mounted in the assembly groove.

In an embodiment, a plurality of assembly grooves are provided, the plurality of assembly grooves are evenly spaced along a circumferential direction of the mounting shell, a plurality of the magnets are provided, and the plurality of the magnets are fitted into the plurality of assembly grooves.

Alternatively, the assembly groove is an annular groove, and the magnet is an arc-shaped magnet.

In an embodiment, the arc-shaped magnet includes a plurality of first magnets successively spliced along the circumferential direction, and magnetic poles of two adjacent first magnets are opposite. Alternatively, the arc-shaped magnet includes at least two second magnets successively spliced along a radial direction, and magnetic poles of two adjacent second magnets are opposite.

In an embodiment, the assembly groove is an annular groove, the magnet is an annular magnet, the annular magnet includes an annular part and an arc-shaped part, and the arc-shaped part is connected to an annular surface of the annular part.

In an embodiment, a cross section of the arc-shaped part is rectangular, trapezoidal or L-shaped.

In an embodiment, the earphone includes a plurality of Hall sensors, the plurality of Hall sensors are spaced along a circumferential direction of the circuit board, and an angle between two adjacent Hall sensors is 15° to 120°.

In an embodiment, when the magnetic knob is rotated to allow the magnet to reach a position closest to the Hall sensor, a spacing between the magnet and the Hall sensor is a, and a≤10 mm.

Additionally or Alternatively, a distance between an axis of the magnet and the Hall sensor is b, and b≤5 mm.

In an embodiment, the housing includes a first housing and a second housing. The circuit board and the Hall sensor are both disposed in the first housing. The second housing is connected to an end of the first housing, a mounting groove is formed at a junction of the first housing and the second housing, and the magnetic knob is rotatably mounted on the mounting groove.

In an embodiment, the first housing includes a housing body and a middle frame. An end of the housing body facing towards the second housing is open. The middle frame is fitted on an open end of the housing body, and the middle frame is provided with a sound-out hole. The circuit board and the Hall sensor are disposed between the middle frame and the housing body, the mounting shell is rotatably fitted on the middle frame, the mounting shell is provided with an avoidance hole and the assembly groove, the magnet is disposed in the assembly groove, the avoidance hole is disposed corresponding to the sound-out hole, and the second housing is fastened on the avoidance hole and connected to the middle frame.

The rotatably controlled earphone further includes a sealing ring. The sealing ring is fitted on one end of the middle frame facing towards the second housing, the sealing ring is positioned at a radial inner side of an inner peripheral wall of the avoidance hole, and the second housing is provided with a sealing protrusion abutting against the sealing ring.

### BRIEF DESCRIPTION OF DRAWINGS

FIG. 1 is a sectional structure view of a rotatably controlled earphone according to embodiment one of the present disclosure;

FIG. 2 is a view illustrating a middle frame mated with a magnet in the rotatably controlled earphone shown in FIG. 1;

FIG. 3 is a sectional structure view of a rotatably controlled earphone according to embodiment two of the present disclosure;

FIG. 4 is a structure view of a first-type magnet of the rotatably controlled earphone according to embodiment two of the present disclosure;

FIG. 5 is a structure view of a second-type magnet of the rotatably controlled earphone according to embodiment two of the present disclosure;

FIG. 6 is a structure view of a third-type magnet of the rotatably controlled earphone according to embodiment two of the present disclosure;

FIG. 7 is a structure view of a fourth-type magnet of the rotatably controlled earphone according to embodiment two of the present disclosure;

FIG. 8 is a structure view of a fifth-type magnet of the rotatably controlled earphone according to embodiment two of the present disclosure;

FIG. 9 is a structure view of a sixth-type magnet of the rotatably controlled earphone according to embodiment two of the present disclosure;

FIG. 10 is a structure view showing a position relationship between of Hall sensors on a circuit board of a rotatably controlled earphone according to an embodiment of the present disclosure; and

FIG. 11 is a structure view showing a position relationship of a magnet and a Hall sensor of a rotatably controlled earphone according to an embodiment of the present disclosure.

### REFERENCE LIST

1 housing body
2 middle frame
21 sound-out hole
3 circuit board
4 Hall sensor
5 mounting shell
51 assembly groove
52 avoidance hole
5 magnet
61 first magnet
62 second magnet
63 annular part
64 arc-shaped part
7 second housing body
71 sealing protrusion
8 sealing ring

### DETAILED DESCRIPTION

To better illustrate the solved technical problems, adopted technical solutions and achieved effects of the present disclosure, the technical solutions of the present disclosure is further described in conjunction with embodiments and drawings.

In the description of the present disclosure, it is to be understood that the orientation or position relationships indicated by terms “center”, “longitudinal”, “lateral”, “length”, “width”, “thickness”, “above”, “below”, “front”, “back”,” “left”, “right”, “vertical”, “horizontal”, “top”, “bottom”, “inside”, “outside”, “clockwise”, “counterclockwise”, “axial direction”, “radial direction”, “circumferential direction” etc. are based on the orientation or position relationships shown in the drawings, merely for facilitating description of the present disclosure and simplifying description, and do not indicate or imply that the apparatus or element referred to has a specific orientation and is constructed and operated in a specific orientation, and thus it is not to be construed as limiting the present disclosure.

In addition, a feature defined as a “first” feature or a “second” feature may explicitly or implicitly include one or more of such features, which is used to distinguish and describe the feature without order or weight. In the description of the present disclosure, unless otherwise noted, “a plurality of” means two or more.

In the description of the present disclosure, it should be noted that unless otherwise expressly specified and limited, terms like “mounted”, “connected to each other”, “connected” are to be construed in a broad sense, for example, as permanently connected, detachably connected or integrally connected; mechanically connected or electrically connected; directly connected or indirectly connected via an intermediate medium; or internally connected of two elements. For those of ordinary skill in the art, specific meanings of the above terms in the present disclosure can be understood according to specific conditions.

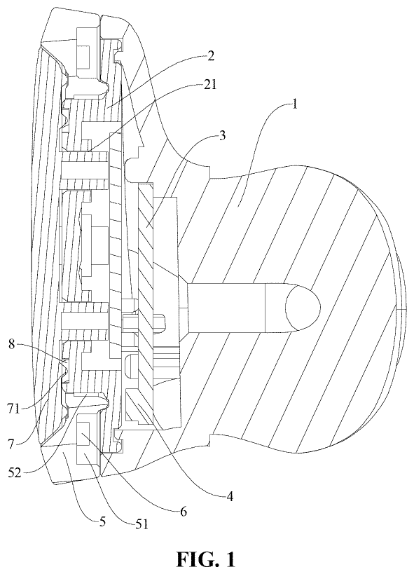

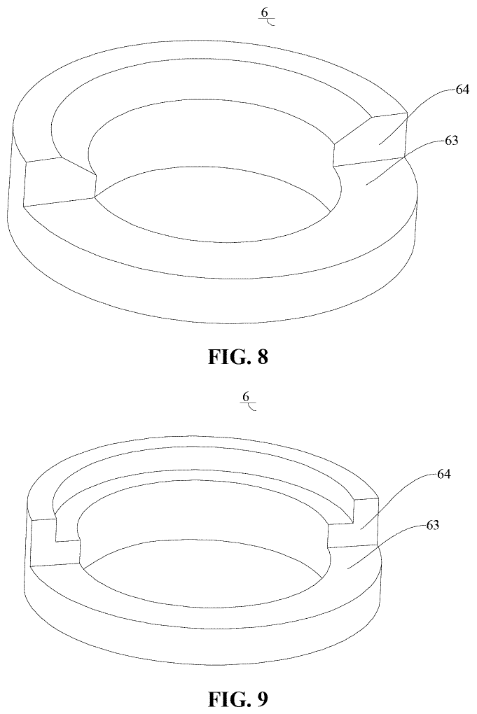

The specific structure of a rotatably controlled earphone according to embodiments of the present disclosure will be described below with reference to FIG. 1 to FIG. 9.

As shown in FIG. 1 to FIG. 3, the present disclosure provides a rotatably controlled earphone. The earphone includes a housing body 1, a middle frame 2, a circuit board 3, a mounting shell 5, and a second housing 7. One end of the housing body 1 is open. A housing of the earphone includes the housing body 1, the middle frame 2, and the second housing 7. The middle frame 2 is fitted on the open end of the housing body 1. The middle frame 2 is provided with a sound-out hole 21, and the circuit board 3 is disposed between the middle frame 2 and the housing body 1. The circuit board 3 is provided with a Hall sensor 4. The mounting shell 5 is rotatably fitted on the middle frame 2, and the mounting shell 5 is provided with an avoidance hole 52 and an assembly groove 51. A magnet 6 is disposed in the assembly groove 51, the avoidance hole 52 is disposed corresponding to the sound-out hole 21, and the second housing 7 is fastened on the avoidance hole 52 and connected to the middle frame 2. When the mounting shell 5 drives the magnet 6 to rotate, the Hall sensor 4 can detect a rotation angle of the magnet 6.

It is to be understood that in actual use, a control chip of the earphone configures the Hall sensor 4 to be in a measurement mode, and at this time the Hall sensor 4 can monitor the magnetic field intensity in real time. When the mounting shell 5 is rotated, the magnet 6 rotates together with the mounting shell 5, so that the magnetic field intensity at a position where the Hall sensor 4 is located changes correspondingly. The Hall sensor 4 can detect the magnetic field intensity in real time and transmit the detected magnetic field intensity to the circuit board 3 of the earphone. The control chip converts the magnetic field intensity detected by the Hall sensor 4 into corresponding rotation direction and rotation angle through calculation, thereby achieving the measurement of the rotation angle and rotation direction of a magnetic knob. When the rotation angle of the magnetic knob reaches a setting threshold, the control chip determines according to conditions, and makes corresponding operations (increase/decrease volume, adjust a depth of noise reduction, switch to a last song or a next song, and the like). That is to say, the earphone of this embodiment can achieve adjustment functions of increasing/decreasing volume, adjusting the depth of noise reduction, switching to the last song or the next song and the like by rotating the magnetic knob, so that the earphone is very convenient to use.

At the same time, in this embodiment, the measurement of the rotation angle and the rotation direction of the magnet 6 is achieved by using the Hall sensor 4 to sense the change of magnetic field. Compared with the existing mode of using the encoder to measure, this embodiment has a simpler structure and lower manufacturing cost.

In addition, since the magnetic knob is disposed on an outer peripheral wall surface of the housing, the arrangement of the magnetic knob has little influence on an overall volume and an internal mounting space of the earphone. More specifically, the magnet 6 is sandwiched between the mounting shell 5 and the middle frame 2, thereby having little influence on the volume of the whole earphone, that is, the earphone of this embodiment can have a smaller volume. In addition, the magnetic knob has a relatively large volume compared with the housing, which is convenient for the user to find the magnetic knob and improves the convenience of operation of the magnetic knob.

Furthermore, for a conventional earphone, a control key is typically disposed on an earphone line, and a position of the earphone line relative to the user is difficult to be fixed, especially when the user is in a moving state, so it is difficult for the user to find the control key under the condition that the user cannot see the control key. In this embodiment, the control key is disposed on the outer peripheral wall surface of the housing and is fixed relative to the user, and a user's hand can easily find the position of his ear without vision. When the earphone is in use, a position of the magnetic knob is positioned at the ear regardless of whether the user is in a moving state or stationary state. Therefore, the user can easily find the position of the magnetic knob, and the arrangement of the magnetic knob has good operation convenience.

More specifically, the housing body 1 has a sound transmission channel through which the earphone transmits sound to the user's ear.

In the rotatably controlled earphone of the embodiments of the present disclosure, since the measurement of the rotation angle and the rotation direction of the magnet 6 is achieved by using the Hall sensor 4 to sense the change of magnetic field, the adjustment functions of increasing/decreasing volume, adjusting the depth of noise reduction, switching to the last song or the next song and the like are achieved by rotating the mounting shell 5. In this way, the using of the earphone is facilitated, the structure of the earphone is simplified, the production cost of the earphone is reduced, and the volume of the earphone is controlled, thereby increasing the using satisfaction of the user.

In some embodiments, as shown in FIG. 3, a plurality of assembly grooves 51 are provided, the plurality of assembly grooves 51 are evenly spaced along a circumferential direction of the mounting shell 5, a plurality of the magnets 6 are provided, and the plurality of the magnets 6 are fitted into the plurality of assembly grooves 51. It is to be understood that the plurality of mounting grooves 51 and the plurality of magnets 6 are provided. That is to say, during one rotation of the mounting shell 5, the magnetic field will change significantly many times, which is beneficial to improving the sensitivity of rotation control of the earphone and further improving the using satisfaction of the user.

In some embodiments, the assembly groove 51 is an annular groove, and the magnet 6 is an arc-shaped magnet. It is to be understood that the arc-shaped magnet 6 facilitates the installation, and enables more significant change of the magnetic field during the rotation of the mounting shell 5, thus facilitating the detection of the Hall sensor 4 and improving the sensitivity of the rotation control of the earphone. In addition, in the embodiments of the present disclosure, the arc-shaped magnet may be in the shape of a circular ring, a semi-circular ring, a quadrant circular ring or the like according to actual needs, and the shape of the arc-shaped magnet may be specifically selected according to actual needs.

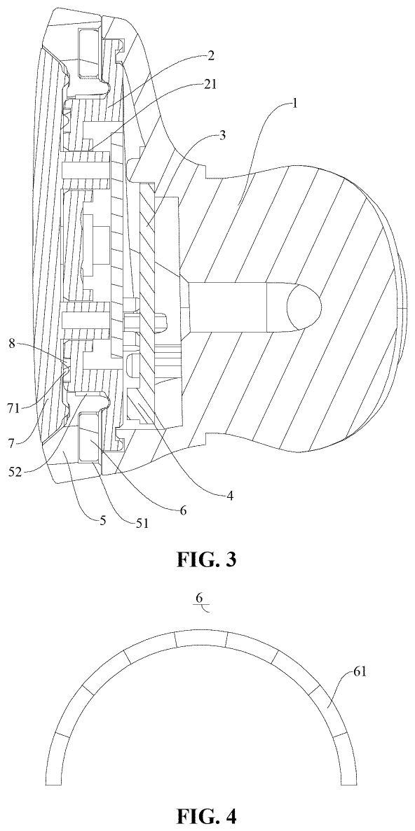

In some specific embodiments, as shown in FIG. 4, the arc-shaped magnet includes a plurality of first magnets 61 successively spliced along the circumferential direction, and magnetic poles of two adjacent first magnets 61 are opposite. Therefore, during one rotation of the mounting shell 5, the magnetic field will change significantly many times, which is beneficial to improving the sensitivity of rotation control of the earphone and further improving the using satisfaction of the user. Of course, in other embodiments of the present disclosure, as shown in FIG. 5, the arc-shaped magnet may further include at least two second magnets 62 successively spliced along a radial direction, and magnetic poles of two adjacent second magnets 62 are opposite. That is to say, in this embodiment, a splicing mode of the arc-shaped magnet may be selected according to actual needs, and is not limited to the above description and limitation.

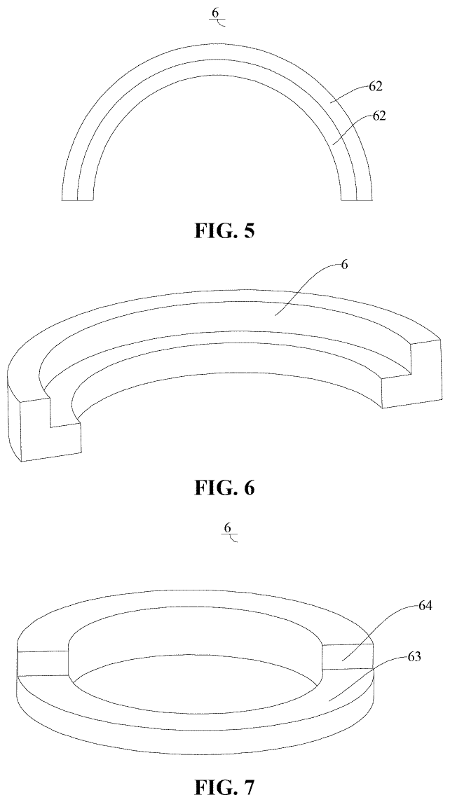

In some embodiments, as shown in FIG. 6 to FIG. 9, the assembly groove 51 is an annular groove, the magnet 6 is an annular magnet, the annular magnet includes an annular part 63 and an arc-shaped part 64, and the arc-shaped part 64 is connected to the annular part 63. Therefore, in the process of installing the magnet 6 conveniently, the amplitude of the change of the magnetic field can be increased during one rotation of the mounting shell 5, thereby facilitating the detection of the Hall sensor 4 and improving the sensitivity of the rotation control of the earphone. In other embodiments, a thickness of the magnet 6 may further change along a circumferential direction of the magnet 6 such that the Hall sensor 4 can also feel the change of the magnetic field intensity when the magnet 6 rotates, thereby achieving controlling the operation of the earphone through the knob.

Specifically, as shown in FIG. 7 to FIG. 9, a cross section of the arc-shaped part 64 is rectangular, trapezoidal or L-shaped. Of course, in other embodiments of the present disclosure, the cross section of the arc-shaped part 64 may be of other shapes and is not limited to the shapes described above.

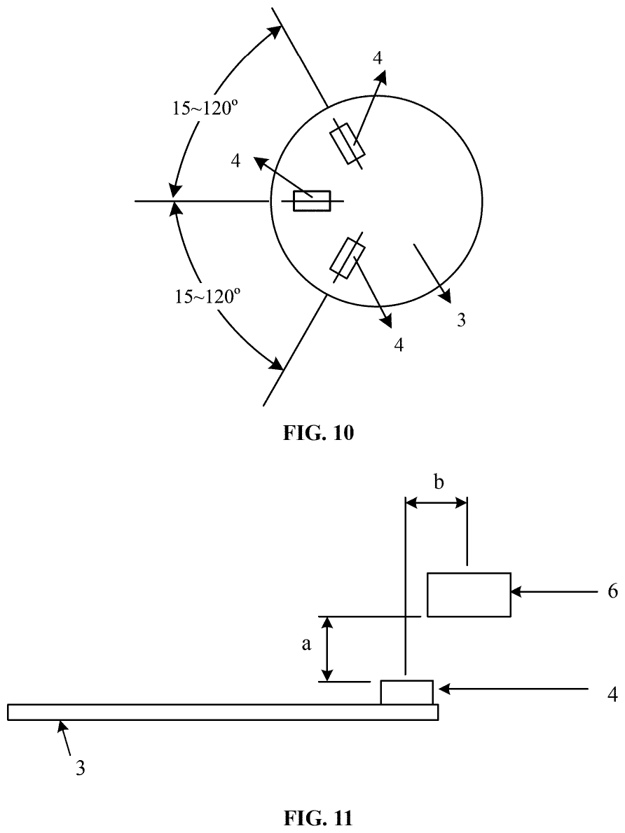

In some embodiments, as shown in FIG. 10, the Hall sensors 4 are spaced along a circumferential direction of the circuit board 3, and an angle between two adjacent Hall sensors 4 is 15° to 120°. It is to be understood that when the plurality of Hall sensors 4 are provided, the progress of magnetic field detection can be improved, thereby improving the sensitivity of the rotation control of the earphone. In this embodiment, the number of Hall sensors 4 can be selected according to actual needs, and the specific number of Hall sensors 4 is not limited herein.

In some embodiments, as shown in FIG. 11, when the magnetic knob is rotated to allow the magnet to reach a position closest to the Hall sensor, a spacing between the magnet 6 and the Hall sensor 4 is a, and a satisfies the formula: a≤10 mm. It is to be understood that when the spacing between the magnet 6 and the Hall sensor 4 is relatively large, it is not conducive to the detection of change of the magnetic field by the Hall sensor 4. In this embodiment, the spacing between the magnet 6 and the Hall sensor 4 is controlled within 10 mm, which can ensure that the Hall sensor 4 can detect the change of the magnetic field more accurately, thereby improving the sensitivity of the rotation control of the earphone. Of course, in other embodiments of the present disclosure, the spacing between the magnet 6 and the Hall sensor 4 may be selected according to actual needs and is not limited to the limitations of this embodiment.

In some embodiments, as shown in FIG. 11, when the magnetic knob is rotated to allow the magnet to reach a position closest to the Hall sensor, a distance between an axis of the magnet 6 and the Hall sensor 4 is b, and b satisfies the formula: b≤5 mm. It is to be understood that the distance between the axis of the magnet 6 and the Hall sensor 4 has certain influence on the detection accuracy of the Hall sensor 4. In this embodiment, the distance between the magnet 6 and the Hall sensor 4 is controlled within 5 mm, which can ensure that the Hall sensor 4 can detect the change of the magnetic field more accurately, thereby improving the sensitivity of the rotation control of the earphone. Of course, in other embodiments of the present disclosure, the distance between the axis of the magnet 6 and the Hall sensor 4 may be selected according to actual needs and is not limited to the limitations of this embodiment.

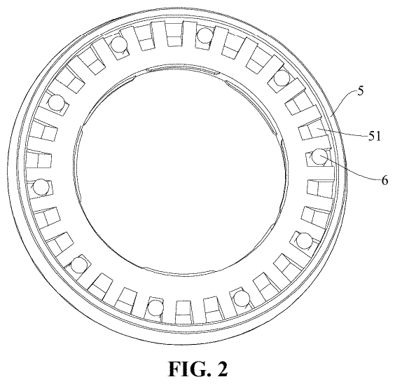

In some embodiments, as shown in FIG. 1 to FIG. 2, the rotatably controlled earphone further includes a sealing ring 8. The sealing ring 8 is fitted on one end of the middle frame 2 facing towards the second housing 7, the sealing ring 8 is positioned at a radial inner side of an inner peripheral wall of the avoidance hole 52, and the second housing 7 is provided with a sealing protrusion 71 abutting against the sealing ring 8. It is to be understood that since the mounting shell 5 can rotate relative to the middle frame 2, the sealing performance of the earphone will be reduced, thus reducing the service life of the earphone. However, in this embodiment, the sealing ring 8 is provided between the middle frame 2 and the second housing 7 and the sealing ring 8 is positioned on the radial inner side of the inner peripheral wall of the avoidance hole 52, so that the sealing performance of the earphone can be improved without affecting the normal rotation of the mounting shell 5, thereby improving the use reliability of the earphone and prolonging the service life of the earphone.

### Embodiment One

The rotatably controlled earphone according to one specific embodiment of the present disclosure will be described below with reference to FIG. 1 to FIG. 2.

As shown in FIG. 1 to FIG. 2, the rotatably controlled earphone of this embodiment includes a housing body 1, a middle frame 2, a circuit board 3, a mounting shell 5, a second housing 7, and a sealing ring 8. One end of the housing body 1 is open. The middle frame 2 is fitted on an open end of the housing body 1. The middle frame 2 is provided with a sound-out hole 21, and the circuit board 3 is disposed between the middle frame 2 and the housing body 1. The circuit board 3 is provided with a Hall sensor 4. The mounting shell 5 is rotatably fitted on the middle frame 2, and the mounting shell 5 is provided with an avoidance hole 52 and an assembly groove 51. Thirty assembly grooves 51 are provided, and the thirty assembly grooves 51 are evenly spaced along a circumferential direction of the mounting shell 5. Ten assembly grooves 51 are provided with magnets 6, and the ten magnets 6 are evenly spaced along the circumferential direction of the mounting shell 5. The avoidance hole 52 is disposed corresponding to the sound-out hole 21, and the second housing 7 is fastened on the avoidance hole 52 and connected to the middle frame 2. When the mounting shell 5 drives the magnet 6 to rotate, the Hall sensor 4 can detect a rotation angle of the magnet 6. The sealing ring 8 is fitted on one end of the middle frame 2 facing towards the second housing 7, the sealing ring 8 is positioned at a radial inner side of an inner peripheral wall of the avoidance hole 52, and the second housing 7 is provided with a sealing protrusion 71 abutting against the sealing ring 8.

### Embodiment Two

The rotatably controlled earphone according to another specific embodiment of the present disclosure will be described below with reference to FIG. 3 to FIG. 9.

The structure of the rotatably controlled earphone of this embodiment is substantially the same as the structure of the rotatably controlled earphone of embodiment one, except that the mounting groove 51 is an annular groove and the magnet 6 may be any one of magnets in FIG. 4 to FIG. 9.

In the description of the specification, the description of reference terms “some embodiments”, “other embodiments” and the like means a specific characteristic, a structure, a material or a feature described in conjunction with the embodiment or the example are included in at least one embodiment or example of the present disclosure. In the specification, the illustrative description of the preceding terms does not necessarily refer to the same embodiment or example. Moreover, the described specific characteristics, structures, materials or features may be combined properly in one or more embodiments or examples.

It is to be noted that the housing and the magnetic knob in this solution are not limited to the above technical scheme. In other embodiments, the housing may also be integrally formed, the outer peripheral wall surface of the housing is provided with an annular guide rail, and the magnetic knob is provided with a sliding groove mated with the annular guide rail, such that the magnetic knob is rotatably connected to the housing, and the installation method of the magnetic knob has no influence on the installation space inside the earphone. Therefore, the internal devices of the earphone can be effectively guaranteed to have a reasonable spatial arrangement, thus ensuring the sound effect of the earphone. In another embodiment, the magnetic knob may be the magnet 6 without the need of housing, and such magnetic knob has the characteristics of simpler processing and lower cost.

In addition, in this solution, the mounting shell 5 and the magnet 6 are not limited to the above technical solution. In other embodiments, the magnet 6 may be embedded in the mounting shell 5. Alternatively, the magnet 6 is bonded to the mounting shell 5. Alternatively, the magnet 6 engages with the mounting shell 5 in a snap fit way, which features convenient installation and facilitates maintenance and replacement.

The above are merely preferred embodiments of the present disclosure. Those of ordinary skill in the art will make modifications in the embodiments and application scope according to the present disclosure. The content of this specification is not to be construed as limiting the present disclosure.

What is claimed is:

1. A rotatably controlled earphone, comprising:
a housing;
a circuit board disposed in the housing;
a Hall sensor disposed in the housing, wherein the Hall sensor is electrically connected to the circuit board; and
a magnetic knob rotatably disposed on an outer peripheral wall surface of the housing, wherein the magnetic knob cooperates with the Hall sensor.

2. The rotatably controlled earphone of claim 1, wherein the magnetic knob comprises a mounting shell and a magnet, the mounting shell has an assembly groove, and the magnet is mounted in the assembly groove.

3. The rotatably controlled earphone of claim 2, wherein a plurality of assembly grooves are provided, the plurality of assembly grooves are evenly spaced along a circumferential direction of the mounting shell, a plurality of the magnets are provided, and the plurality of the magnets are fitted into the plurality of assembly grooves; or
the assembly groove is an annular groove, and the magnet is an arc-shaped magnet.

4. The rotatably controlled earphone of claim 3, wherein the arc-shaped magnet comprises a plurality of first magnets successively spliced along the circumferential direction, and magnetic poles of two adjacent ones of the plurality of first magnets are opposite; or the arc-shaped magnet comprises at least two second magnets successively spliced along a radial direction, and magnetic poles of two adjacent ones of the at least two second magnets are opposite.

5. The rotatably controlled earphone of claim 2, wherein the assembly groove is an annular groove, the magnet is an annular magnet, the annular magnet comprises an annular part and an arc-shaped part, and the arc-shaped part is connected to an annular surface of the annular part.

6. The rotatably controlled earphone of claim 5, wherein a cross section of the arc-shaped part is rectangular, trapezoidal or L-shaped.

7. The rotatably controlled earphone of claim 1, wherein the earphone comprises a plurality of Hall sensors, the plurality of Hall sensors are spaced along a circumferential direction of the circuit board, and an angle between two adjacent ones of the plurality of Hall sensors is 15° to 120°.

8. The rotatably controlled earphone of claim 2, wherein when the magnetic knob is rotated to allow the magnet to reach a position closest to the Hall sensor, a position relationship of the magnet and the Hall sensor comprises at least one of the following:
a spacing between the magnet and the Hall sensor is a, and a≤10 mm; or
a distance between an axis of the magnet and the Hall sensor is b, and b≤5 mm.

9. The rotatably controlled earphone of claim 2, wherein the housing comprises:
a first housing, wherein the circuit board and the Hall sensor are both disposed in the first housing; and
a second housing, wherein the second housing is connected to an end of the first housing, a mounting groove is formed at a junction of the first housing and the second housing, and the magnetic knob is rotatably mounted on the mounting groove.

10. The rotatably controlled earphone of claim 9, wherein the first housing comprises:
a housing body, wherein an end of the housing body facing towards the second housing is open; and
a middle frame, wherein the middle frame is fitted on the open end of the housing body, and the middle frame is provided with a sound-out hole; wherein
the circuit board and the Hall sensor are disposed between the middle frame and the housing body, the mounting shell is rotatably fitted on the middle frame, the mounting shell is provided with an avoidance hole and the assembly groove, the magnet is disposed in the assembly groove, the avoidance hole is disposed corresponding to the sound-out hole, and the second housing is fastened on the avoidance hole and connected to the middle frame; and
the rotatably controlled earphone further comprises:
a sealing ring, wherein the sealing ring is fitted on one end of the middle frame facing towards the second housing, the sealing ring is positioned at a radial inner side of an inner peripheral wall of the avoidance hole, and the second housing is provided with a sealing protrusion abutting against the sealing ring.

11. The rotatably controlled earphone of claim 2, wherein the earphone comprises a plurality of Hall sensors, the plurality of Hall sensors are spaced along a circumferential direction of the circuit board, and an angle between two adjacent ones of the plurality of Hall sensors is 15° to 120°.

12. The rotatably controlled earphone of claim 3, wherein the earphone comprises a plurality of Hall sensors, the plurality of Hall sensors are spaced along a circumferential direction of the circuit board, and an angle between two adjacent ones of the plurality of Hall sensors is 15° to 120°.

13. The rotatably controlled earphone of claim 4, wherein the earphone comprises a plurality of Hall sensors, the plurality of Hall sensors are spaced along a circumferential direction of the circuit board, and an angle between two adjacent ones of the plurality of Hall sensors is 15° to 120°.

14. The rotatably controlled earphone of claim 5, wherein the earphone comprises a plurality of Hall sensors, the plurality of Hall sensors are spaced along a circumferential direction of the circuit board, and an angle between two adjacent ones of the plurality of Hall sensors is 15° to 120°.

15. The rotatably controlled earphone of claim 6, wherein the earphone comprises a plurality of Hall sensors, the plurality of Hall sensors are spaced along a circumferential direction of the circuit board, and an angle between two adjacent ones of the plurality of Hall sensors is 15° to 120°.

16. The rotatably controlled earphone of claim 3, wherein when the magnetic knob is rotated to allow the magnet to reach a position closest to the Hall sensor, a position relationship of the magnet and the Hall sensor comprises at least one of the following:
a spacing between the magnet and the Hall sensor is a, and a≤10 mm; or
a distance between an axis of the magnet and the Hall sensor is b, and b≤5 mm.

17. The rotatably controlled earphone of claim 4, wherein when the magnetic knob is rotated to allow the magnet to reach a position closest to the Hall sensor, a position relationship of the magnet and the Hall sensor comprises at least one of the following:
a spacing between the magnet and the Hall sensor is a, and a≤10 mm; or
a distance between an axis of the magnet and the Hall sensor is b, and b≤5 mm.

18. The rotatably controlled earphone of claim 5, wherein when the magnetic knob is rotated to allow the magnet to reach a position closest to the Hall sensor, a position relationship of the magnet and the Hall sensor comprises at least one of the following:
a spacing between the magnet and the Hall sensor is a, and a≤10 mm; or
a distance between an axis of the magnet and the Hall sensor is b, and b≤5 mm.

19. The rotatably controlled earphone of claim 6, wherein when the magnetic knob is rotated to allow the magnet to reach a position closest to the Hall sensor, a position relationship of the magnet and the Hall sensor comprises at least one of the following:
a spacing between the magnet and the Hall sensor is a, and a≤10 mm; or
a distance between an axis of the magnet and the Hall sensor is b, and b≤5 mm.
